(19) United States
(12) Patent Application Publication
(10) Pub. No.: US 2024/0014797 A1
(43) Pub. Date: Jan. 11, 2024

(54) ACOUSTIC WAVE DEVICE AND ACOUSTIC WAVE DEVICE MANUFACTURING METHOD

(71) Applicant: Murata Manufacturing Co., Ltd., Nagaokakyo-shi (JP)

(72) Inventor: Kazunori INOUE, Nagaokakyo-shi (JP)

(21) Appl. No.: 18/370,690

(22) Filed: Sep. 20, 2023

Related U.S. Application Data
(63) Continuation of application No. PCT/JP2022/016876, filed on Mar. 31, 2022.
(60) Provisional application No. 63/168,331, filed on Mar. 31, 2021.

(51) Int. Cl. H03H 9/02; H03H 3/02; H03H 9/13; H03H 9/17

(52) U.S. Cl. CPC H03H 9/02157; H03H 9/02015; H03H 3/02; H03H 9/132; H03H 9/173; H03H 2003/021

(57) ABSTRACT

An acoustic wave device includes a support substrate with a thickness in a first direction, an intermediate layer on the support substrate, a piezoelectric layer adjacent to the support substrate in the first direction, and a functional electrode on the piezoelectric layer. A cavity is provided in the intermediate layer. The intermediate layer includes a first portion and a second portion. The first portion is closer to the cavity than the second portion. The first portion or the second portion is modified.

### CROSS REFERENCE TO RELATED APPLICATIONS

This application claims the benefit of priority to Provisional Application No. 63/168,331 filed on Mar. 31, 2021 and is a Continuation Application of PCT Application No. PCT/JP2022/016876 filed on Mar. 31, 2022. The entire contents of each application are hereby incorporated herein by reference.

### BACKGROUND OF THE INVENTION

### 1. Field of the Invention

The present disclosure relates to an acoustic wave device and an acoustic wave device manufacturing method.

### 2. Description of the Related Art

An acoustic wave device is described in Japanese Unexamined Patent Application Publication No. 2012-257019.

In Japanese Unexamined Patent Application Publication No. 2012-257019, a through hole to be connected to a cavity may be provided, and a sacrificial layer in the region that will become the cavity may be etched via the through hole. The sacrificial layer is surrounded by an intermediate layer that remains after the etching. The intermediate layer is a residual layer of a different material from the sacrificial layer, but the boundary between the sacrificial layer and the intermediate layer is uneven and consequently the film thickness of a piezoelectric layer is likely to vary.

### SUMMARY OF THE INVENTION

Preferred embodiments of the present invention improve a film thickness accuracy of a piezoelectric layer.

An acoustic wave device according to a preferred embodiment of the present invention includes a support substrate with a thickness in a first direction, an intermediate layer on the support substrate, a piezoelectric layer adjacent to the support substrate in the first direction, and a functional electrode on the piezoelectric layer. A cavity is provided in the intermediate layer. The intermediate layer includes a first portion and a second portion. The first portion is closer to the cavity than the second portion. The first portion is more soluble in a prescribed etchant than the second portion.

An acoustic wave device according to a preferred embodiment of the present invention includes a support substrate with a thickness in a first direction, an intermediate layer on the support substrate, a piezoelectric layer adjacent to the support layer in the first direction, and a functional electrode on the piezoelectric layer. A cavity is provided in the intermediate layer. The intermediate layer includes a first portion and a second portion. The first portion is closer to the cavity than the second portion. The first portion is less soluble in a prescribed etchant than the second portion.

An acoustic wave device according to a preferred embodiment of the present invention includes a support substrate with a thickness in a first direction, an intermediate layer on the support substrate, a piezoelectric layer adjacent to the support substrate in the first direction, and a functional electrode on the piezoelectric layer. A cavity is provided in the intermediate layer. The intermediate layer includes a first portion and a second portion. The first portion is closer to the cavity than the second portion. The first portion and the second portion have different degrees of carbonization or crystallization from each other.

An acoustic wave device manufacturing method according to a preferred embodiment of the present invention includes bonding a support substrate and a piezoelectric layer to each other via an intermediate layer, after the bonding, forming and modifying a first portion of the intermediate layer surrounded by a second portion of the intermediate layer and being more soluble in a prescribed etchant than the second portion, and forming a cavity by dissolving the first portion of the intermediate layer formed in the forming the first portion.

According to preferred embodiments of the present disclosure, the film thickness accuracy of a piezoelectric layer is improved.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view illustrating an acoustic wave device of a preferred embodiment of the present invention.

FIG. 1B is a plan view illustrating an electrode structure of a preferred embodiment of the present invention.

FIG. 2 is a sectional view taken along line II-II in FIG. 1A.

FIG. 3A is a schematic sectional view for describing Lamb waves propagating through a piezoelectric layer of a comparative example.

FIG. 3B is a schematic sectional view for illustrating thickness-shear first-order-mode bulk waves propagating through a piezoelectric layer of a preferred embodiment of the present invention.

FIG. 4 is a schematic sectional view for illustrating thickness-shear first-order-mode bulk waves propagating through a piezoelectric layer of a preferred embodiment of the present invention.

FIG. 5 is an explanatory diagram illustrating an example of the resonance characteristics of an acoustic wave device of a preferred embodiment of the present invention.

FIG. 6 is an explanatory diagram illustrating the relationship between d/2p and the relative bandwidth of a resonator, where p is the center-to-center distance between adjacent electrodes or the average value of center-to-center distances and d is the average thickness of a piezoelectric layer in an acoustic wave device of a preferred embodiment of the present invention.

FIG. 7 is a plan view illustrating an example in which a pair of electrodes is provided in an acoustic wave device of a preferred embodiment of the present invention.

FIG. 8 is a reference diagram illustrating an example of resonance characteristics of an acoustic wave device of a preferred embodiment of the present invention.

FIG. 9 is an explanatory diagram illustrating the relationship between the relative bandwidth of an acoustic wave device of a preferred embodiment of the present invention and the amount of phase rotation of the impedance of spurious normalized using 180 degrees as the magnitude of the spurious when a number of acoustic wave resonators are configured in an acoustic wave device of a preferred embodiment of the present invention.

FIG. 10 is an explanatory diagram illustrating the relationship between d/2p, the metallization ratio MR, and the relative bandwidth.

FIG. 11 is an explanatory diagram illustrating a relative bandwidth map for the Euler angles (0°, θ, ψ) of LiNbO₃ when d/p is as close to 0 as possible.

FIG. 12 is a partially cut-away perspective view for describing an acoustic wave device according to a preferred embodiment of the present invention.

FIG. 13 is a plan view of an acoustic wave device according to a First Preferred Embodiment of the present invention.

FIG. 14 is a diagram illustrating a cross section taken along line XIV-XIV in FIG. 13.

FIG. 15A is a diagram illustrating a bonding step of an acoustic wave device manufacturing method according to a preferred embodiment of the present invention.

FIG. 15B is a diagram illustrating an electrode forming step of an acoustic wave device manufacturing method according to a preferred embodiment of the present invention.

FIG. 15C is a diagram illustrating an opening forming step of an acoustic wave device manufacturing method according to a preferred embodiment of the present invention.

FIG. 15D is a diagram illustrating a modifying step of an acoustic wave device manufacturing method according to a preferred embodiment of the present invention.

FIG. 15E is a diagram illustrating an etching step of an acoustic wave device manufacturing method according to a preferred embodiment of the present invention.

FIG. 16 is a flowchart illustrating an example of an acoustic wave device manufacturing method of a First Preferred Embodiment of the present invention.

FIG. 17 is a diagram illustrating another example of a cross section taken along line XIV-XIV in FIG. 13 in a Second Preferred Embodiment of the present invention.

FIG. 18A is a diagram illustrating a bonding step of an acoustic wave device manufacturing method according to a preferred embodiment of the present invention.

FIG. 18B is a diagram illustrating an electrode forming step of an acoustic wave device manufacturing method according to a preferred embodiment of the present invention.

FIG. 18C is a diagram illustrating an opening forming step of an acoustic wave device manufacturing method according to a preferred embodiment of the present invention.

FIG. 18D is a diagram illustrating a modifying step of an acoustic wave device manufacturing method according to a preferred embodiment of the present invention.

FIG. 18E is a diagram illustrating an etching step of an acoustic wave device manufacturing method according to a preferred embodiment of the present invention.

FIG. 19 is a diagram illustrating an example of a cross section taken along line XIV-XIV in FIG. 13 in a Third Preferred Embodiment of the present invention.

FIG. 20A is a diagram illustrating a bonding step of an acoustic wave device manufacturing method according to a preferred embodiment of the present invention.

FIG. 20B is a diagram illustrating a modifying step of an acoustic wave device manufacturing method according to a preferred embodiment of the present invention.

FIG. 20C is a diagram illustrating an electrode forming step of an acoustic wave device manufacturing method according to a preferred embodiment of the present invention.

FIG. 20D is a diagram illustrating an opening forming step of an acoustic wave device manufacturing method according to a preferred embodiment of the present invention.

FIG. 20E is a diagram illustrating an etching step of an acoustic wave device manufacturing method according to a preferred embodiment of the present invention.

FIG. 21 is a flowchart illustrating an example of an acoustic wave device manufacturing method according to a preferred embodiment of the present invention.

FIG. 22 is a diagram illustrating an example of a cross section taken along line XIV-XIV in FIG. 13 in a modification of a Third Preferred Embodiment of the present invention.

FIG. 23 is a diagram illustrating another example of a cross section of a functional electrode in a Fourth Preferred Embodiment of the present invention.

### DETAILED DESCRIPTION OF THE PREFERRED EMBODIMENTS

Hereafter, preferred embodiments of the present disclosure will be described in detail with reference to the drawings. The present disclosure is not limited by the preferred embodiments described herein. The preferred embodiments described in the present disclosure are illustrative examples, and descriptions of modifications in which portions of configurations of different preferred embodiments can be substituted for one another or combined with one another are possible and descriptions of matters common to the First Preferred Embodiment are omitted from the Second Preferred Embodiment and subsequent preferred embodiments, and only the points that are different are described. In particular, the same advantageous operational effects resulting from the same or corresponding configurations will not be repeatedly described in the individual preferred embodiments.

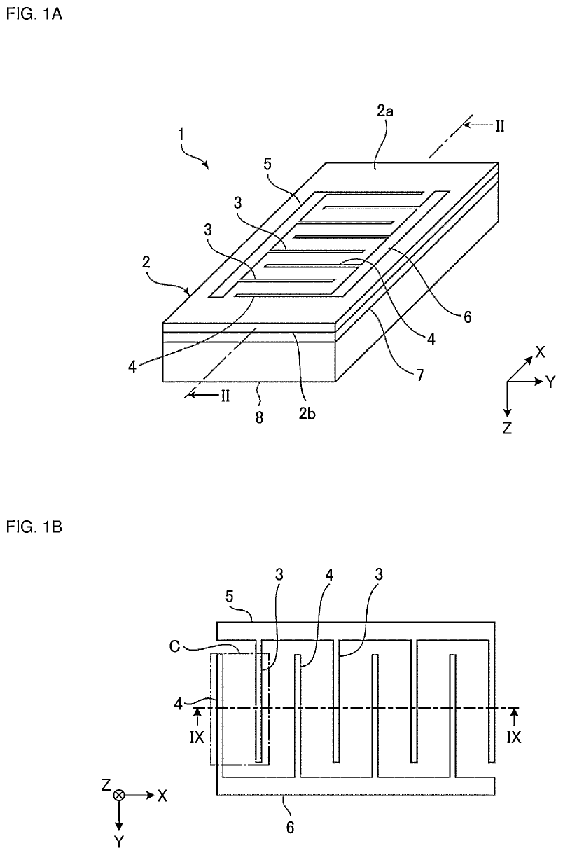

FIG. 1A is a perspective view illustrating an acoustic wave device according to a preferred embodiment of the present invention. FIG. 1B is a plan view illustrating the electrode structure of this preferred embodiment.

An acoustic wave device 1 of this preferred embodiment includes a piezoelectric layer 2 made of, for example, LiNbO₃. The piezoelectric layer 2 may instead be made of, for example, LiTaO₃. The cut angle of LiNbO₃ and LiTaO₃ is a Z-cut angle in this preferred embodiment. The cut angle of LiNbO₃ and LiTaO₃ may instead be a rotated Y-cut or X-cut angle. Y-propagation and X-propagation±about 30° propagation orientations are preferred.

The thickness of the piezoelectric layer 2 is not particularly limited, but a thickness of, for example, from about 50 nm to about 1000 nm is preferred in order to effectively excite a thickness-shear first-order mode.

The piezoelectric layer 2 includes a first main surface 2a and a second main surface 2b, which face each other in a Z direction. Electrode fingers 3 and electrode fingers 4 are provided on the first main surface 2a.

Here, the electrode fingers 3 are an example of “first electrode fingers” and the electrode fingers 4 are an example of “second electrode fingers”. In FIGS. 1A and 1B, a plurality of electrode fingers 3 are a plurality of “first electrode fingers” connected to a first busbar electrode 5. A plurality of electrode fingers 4 are a plurality of “second electrode fingers” connected to a second busbar electrode 6. The plurality of electrode fingers 3 and the plurality of electrode fingers 4 are interdigitated with each other. Thus, a functional electrode 30 including the electrode fingers 3, the electrode fingers 4, the first busbar electrode 5, and the second busbar electrode 6 is provided. The functional electrode 30 may also be referred to as an interdigital transducer (IDT) electrode.

The electrode fingers 3 and 4 are rectangular or substantially rectangular in shape and have a length direction. The electrode fingers 3 and the electrode fingers 4 adjacent to the electrode fingers 3 face each other in a direction perpendicular or substantially perpendicular to the length direction. The length direction of the electrode fingers 3 and 4 and a direction perpendicular or substantially perpendicular to the length direction of the electrode fingers 3 and 4 both intersect a thickness direction of the piezoelectric layer 2. Therefore, it can be said that the electrode fingers 3 and the electrode fingers 4 adjacent to the electrode fingers 3 face each other in a direction that intersects the thickness direction of piezoelectric layer 2. In the following description, the thickness direction of the piezoelectric layer 2 may be referred to as a Z direction (or a first direction), the length direction of the electrode fingers 3 and 4 may be referred to as a Y direction (or a second direction), and a direction perpendicular or substantially perpendicular to the electrode fingers 3 and 4 may be referred to as an X direction (or a third direction).

The length direction of electrode fingers 3 and 4 may be interchanged with a direction perpendicular or substantially perpendicular to the length direction of electrode fingers 3 and 4 illustrated in FIGS. 1A and 1B. In other words, in FIGS. 1A and FIG. 1B, the electrode fingers 3 and 4 may extend in the direction in which the first and second busbar electrodes 5 and 6 extend. In this case, the first and second busbar electrodes 5 and 6 will extend in a direction in which the electrode fingers 3 and 4 extend in FIG. 1A and FIG. 1B. A pair structure including an electrode finger 3 connected to one potential and an electrode finger 4 connected to another potential that are adjacent to each other, and a plurality of this pair structure are provided in a direction perpendicular or substantially perpendicular to the length direction of the electrode fingers 3 and 4.

Here, an electrode finger 3 and an electrode finger 4 are adjacent to each other does not mean that the electrode finger 3 and the electrode finger 4 are disposed so as to be in direct contact with each other, but rather that the electrode finger 3 and the electrode finger 4 are disposed with a spacing therebetween. When an electrode finger 3 and an electrode finger 4 are adjacent to each other, no electrodes connected to a hot electrode or a ground electrode, including other electrode fingers 3 and 4, are disposed between the electrode finger 3 and the electrode finger 4. The number of pairs does not have to be an integer number of pairs, and there may be 1.5 pairs, 2.5 pairs, and so on.

The distance between the centers of the electrode fingers 3 and 4, i.e., the pitch is preferably, for example, greater than or equal to about 1 μm and less than or equal to about 10 μm. The distance between centers of the electrode fingers 3 and 4 is the distance between the center of the width dimension of the electrode finger 3 in a direction perpendicular or substantially perpendicular to the length direction of the electrode finger 3 and the center of the width dimension of the electrode finger 4 in a direction perpendicular or substantially perpendicular to the length direction of the electrode finger 4.

Furthermore, when there are a plurality of at least either one of an electrode finger 3 and an electrode finger 4 (when there are 1.5 or more pairs of electrode fingers 3 and 4 where an electrode finger 3 and an electrode finger 4 constitute a pair of electrodes), the distance between the centers of the electrode fingers 3 and 4 is the average value of the distances between the centers of each pair of adjacent electrode fingers 3 and 4 among the 1.5 or more pairs of the electrode fingers 3 and 4.

The width of electrode fingers 3 and 4, i.e., the dimension in the direction in which the electrode fingers 3 and 4 face each other, is preferably, for example, in a range from about 150 nm to about 1000 nm. The distance between centers of the electrode fingers 3 and 4 is the distance between the center of the dimension (width dimension) of the electrode finger 3 in a direction perpendicular or substantially perpendicular to the length direction of the electrode finger 3 and the center of the dimension (width dimension) of the electrode finger 4 in a direction perpendicular or substantially perpendicular to the length direction of the electrode finger 4.

In this preferred embodiment, since a Z-cut piezoelectric layer is used, a direction perpendicular or substantially perpendicular to the length direction of the electrode fingers 3 and 4 is perpendicular or substantially perpendicular to the polarization direction of the piezoelectric layer 2. This is not the case if a piezoelectric layer of another cut angle is used as the piezoelectric layer 2. Here, “perpendicular” is not limited to meaning strictly perpendicular, and can also mean substantially perpendicular (the angle between the direction perpendicular to the length direction of the electrode fingers 3 and 4 and the polarization direction may lie within a range of about 90°±10° for example).

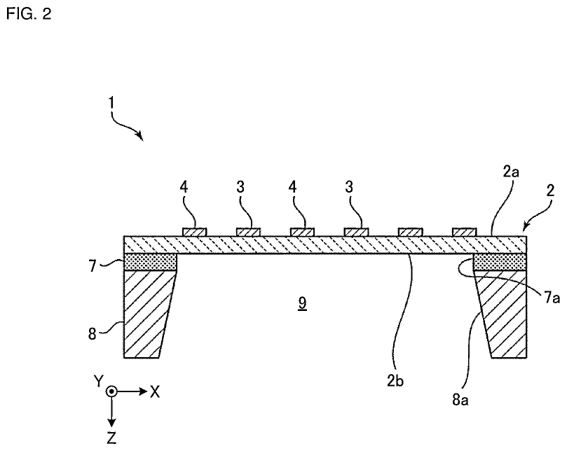

A support substrate 8 is stacked on the second main surface 2b side of the piezoelectric layer 2 with an intermediate layer 7 interposed therebetween. The intermediate layer 7 and the support substrate 8 have a frame shape and include openings 7a and 8a as illustrated in FIG. 2. Thus, a cavity (air gap) 9 is provided.

The cavity 9 is provided so as not to interfere with the vibration of an excitation region C of the piezoelectric layer 2. Therefore, the support substrate 8 is stacked on the second main surface 2b with the intermediate layer 7 interposed therebetween at a position where the support substrate 8 does not overlap a portion where at least one pair of electrode fingers 3 and 4 is provided. The intermediate layer 7 does not have to be provided. Therefore, the support substrate 8 can be directly or indirectly stacked on the second main surface 2b of the piezoelectric layer 2.

The intermediate layer 7 is made of, for example, silicon oxide. However, other than silicon oxide, the intermediate layer 7 can be made of any suitable insulating material such as, for example, silicon nitride, alumina, and so on. The intermediate layer 7 is an example of an “intermediate layer”.

The support substrate 8 is made of, for example, Si. The plane orientation of Si on the piezoelectric layer 2 side may be (100) or (110), or even (111). High-resistance Si having a resistivity of, for example, about 4 kΩ or higher is preferable. However, the support substrate 8 may also be made using an appropriate insulating material or semiconductor material. For example, a piezoelectric material such as aluminum oxide, lithium tantalate, lithium niobate, or quartz, any of various ceramic materials such as alumina, magnesia, sapphire, silicon nitride, aluminum nitride, silicon carbide, zirconia, cordierite, mullite, steatite, or forsterite, a dielectric material such as diamond or glass, or a semiconductor such as gallium nitride can be used as the material of the support substrate 8.

The plurality of electrode fingers 3 and 4 and the first and second busbar electrodes 5 and 6 are made of a suitable metal or alloy such as, for example, Al or an AlCu alloy.

In this preferred embodiment, the electrode fingers 3, the electrode fingers 4, the first busbar electrode 5, and the second busbar electrode 6 have a structure in which, for example, an Al film is stacked on a Ti film. A film other than a Ti film may be used as an adhesive layer.

When driving is performed, an AC voltage is applied between the plurality of electrode fingers 3 and the plurality of electrode fingers 4. More specifically, an AC voltage is applied between the first busbar electrode 5 and the second busbar electrode 6. In this way, resonance characteristics can be obtained using thickness-shear first-order-mode bulk waves excited in the piezoelectric layer 2.

In the acoustic wave device 1, when d represents the thickness of the piezoelectric layer 2 and p represents the distance between the centers of any adjacent electrode fingers 3 and 4 of the plurality of pairs of electrode fingers 3 and 4, d/p is less than or equal to about 0.5, for example. Therefore, bulk waves of a thickness-shear first-order mode are effectively excited and good resonance characteristics can be obtained. More preferably, d/p is less than or equal to 0.24, for example, and in this case, even better resonance characteristics can be obtained.

When there are a plurality of at least either the electrode fingers 3 or the electrode fingers 4 as in this preferred embodiment, that is, when there are 1.5 pairs or more of the electrode fingers 3 and the electrode fingers 4 where a pair of electrodes consists of an electrode finger 3 and an electrode finger 4, the distance p between the centers of adjacent electrode fingers 3 and electrode fingers 4 is the average value of the distances between the centers of the adjacent electrode fingers 3 and 4.

As a result of the acoustic wave device 1 of this preferred embodiment having the above-described configuration, even if the number of pairs of the electrode fingers 3 and 4 is reduced in order to facilitate size reduction, the Q value is unlikely to be degraded. This is because the resonator does not require reflectors on both sides and has low propagation loss. The reason why the reflectors are not needed is due to the use of thickness-shear first-order-mode bulk waves.

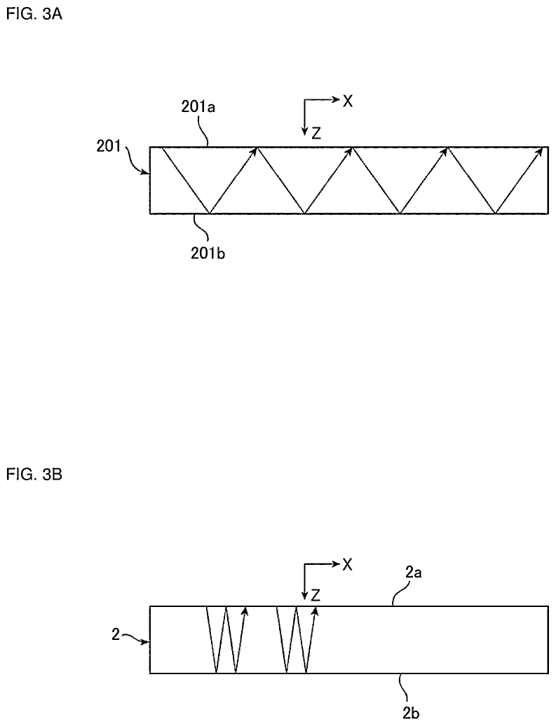

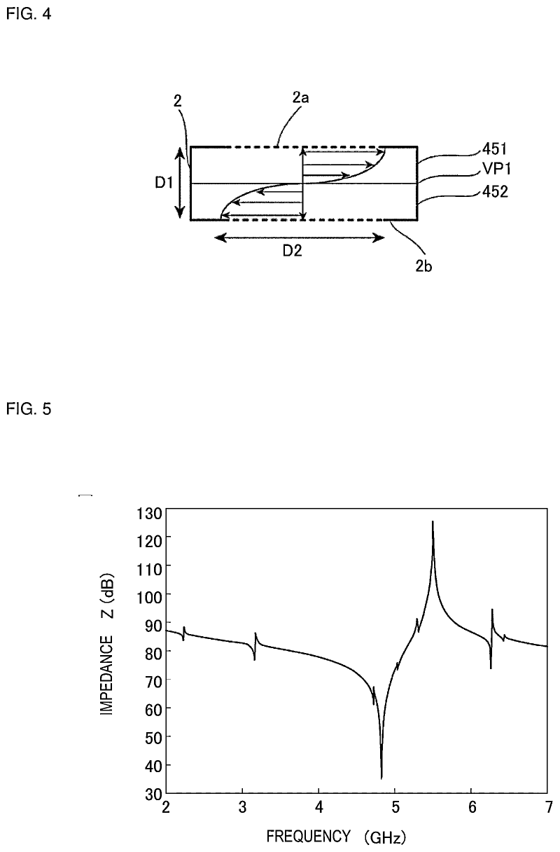

FIG. 3A is a schematic sectional view for describing Lamb waves propagating through a piezoelectric layer of a comparative example. FIG. 3B is a schematic sectional view for illustrating thickness-shear first-order-mode bulk waves propagating through a piezoelectric layer of this preferred embodiment. FIG. 4 is a schematic sectional view for illustrating thickness-shear first-order-mode bulk waves propagating through a piezoelectric layer of this preferred embodiment.

In FIG. 3A, the acoustic wave device is as described in Japanese Unexamined Patent Application Publication No. 2012-257019 and Lamb waves propagate through the piezoelectric layer. As illustrated in FIG. 3A, waves propagate through a piezoelectric layer 201 as indicated by arrows. The piezoelectric layer 201 includes a first main surface 201a and a second main surface 201b, and a thickness direction connecting the first main surface 201a and the second main surface 201b to each other is a Z direction. An X direction is the direction in which the electrode fingers 3 and 4 of the functional electrode 30 are arranged. As illustrated in FIG. 3A, a Lamb wave propagates in the X direction, as illustrated in FIG. 3A. The entire piezoelectric layer 201 vibrates because plate waves are used and the waves propagate in the X direction, and therefore reflectors are disposed on both sides in order to obtain resonance characteristics. Therefore wave propagation loss occurs, and when size reduction is attempted, i.e., when the number of pairs of electrode fingers 3 and 4 is reduced, the Q value decreases.

In contrast, as illustrated in FIG. 3B, in the acoustic wave device of this preferred embodiment, vibrational displacement occurs in the thickness shear direction, and therefore the waves propagate and resonate substantially in a direction connecting the first and second main surfaces 2a and 2b of the piezoelectric layer 2 to each other, i.e., the Z direction. In other words, the X-direction component of the waves is significantly smaller than the Z-direction component of the waves. Since resonance characteristics are obtained as a result of the propagation of the waves in the Z direction, no reflectors are required. Therefore, there is no propagation loss from propagation occurs in the reflectors. Therefore, even if the number of pairs of electrodes consisting of the electrode fingers 3 and 4 is reduced in order to facilitate size reduction, the Q value is unlikely to decrease.

Bulk waves of the thickness-shear first-order mode have opposite amplitude directions in a first region 451, which is included in the excitation region C (refer to FIG. 1B) of the piezoelectric layer 2, and in a second region 452, which is included in the excitation region C, as illustrated in FIG. 4. In FIG. 4, the bulk wave is illustrated in a schematic manner for a case where a voltage is applied between an electrode finger 3 and an electrode finger 4, with the electrode finger 4 being at a higher potential than the electrode finger 3. The first region 451 is a region of the excitation region C between a virtual plane VP1, which is perpendicular or substantially perpendicular to the thickness direction of the piezoelectric layer 2 and divides the piezoelectric layer 2 into two regions, and the first main surface 2a. The second region 452 is the region of the excitation region C between the virtual plane VP1 and the second main surface 2b.

At least one pair of electrodes including an electrode finger 3 and an electrode finger 4 is disposed in the acoustic wave device 1. However, since the waves do not propagate in the X direction, there does not necessarily need to be a plurality of pairs of electrodes consisting of these electrode fingers 3 and 4. In other words, at least one pair of electrodes is all that is required.

For example, the electrode fingers 3 are electrodes connected to a hot potential and the electrode fingers 4 are electrodes connected to the ground potential. However, the electrode fingers 3 may be connected to the ground potential and the electrode fingers 4 may be connected to the hot potential. In this preferred embodiment, at least one pair of electrodes consists of an electrode connected to a hot potential and an electrode connected to the ground potential, as described above, and no floating electrodes are provided.

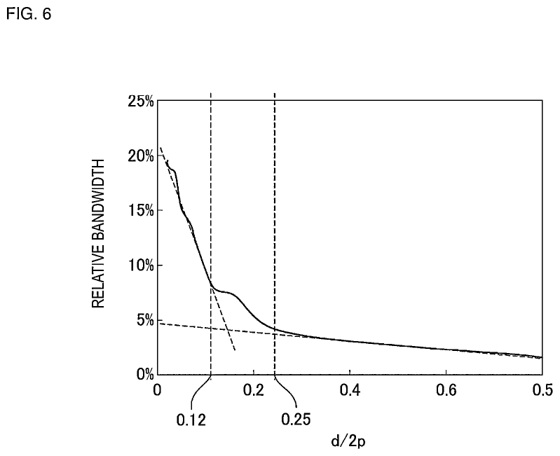

FIG. 5 is an explanatory diagram illustrating an example of the resonance characteristics of the acoustic wave device of this preferred embodiment. The design parameters of the acoustic wave device 1 with which the resonances characteristics illustrated in FIG. 5 were obtained are as follows.
Piezoelectric layer 2: LiNbO₃ with Euler angles (0°, 0°, 90°)
Thickness of piezoelectric layer 2: about 400 nm
Length of excitation region C (refer to FIG. 1B): about 40 μm
Number of pairs of electrodes consisting of electrode fingers 3 and 4: 21 pairs
Distance between centers of electrode fingers 3 and 4 (pitch): about 3 μm
   Width of electrode fingers 3 and 4: about 500 nm
   d/p: about 0.133
   Intermediate layer 7: about 1 μm thick silicon oxide film
   Support substrate 8: Si

The excitation region C (refer to FIG. 1B) is the region where the electrode fingers 3 and 4 overlap when viewed in the X direction, which is perpendicular or substantially perpendicular to the length direction of the electrode fingers 3 and 4. The length of the excitation region C is the dimension along the length direction of the electrode fingers 3 and 4 in the excitation region C. Here, the excitation region C is an example of a “crossing region”.

In this preferred embodiment, the distance between electrodes of the electrode pairs including the electrode fingers 3 and 4 is equal or substantially equal in all of the plurality of pairs. In other words, the electrode fingers 3 and 4 are disposed at a uniform or substantially uniform pitch.

It is clear from FIG. 5 that good resonance characteristics with a relative bandwidth of, for example, about 12.5% are obtained despite there being no reflectors.

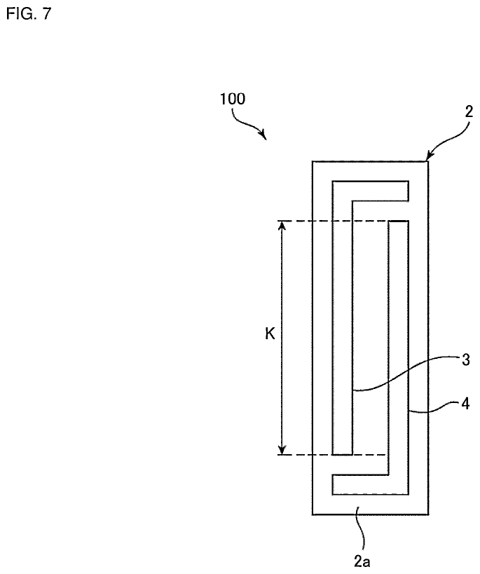

Incidentally, when d represents the thickness of the piezoelectric layer 2 and p represents the distance between the centers of the electrode fingers 3 and 4, in this preferred embodiment, d/p is, for example, less than or equal to about 0.5, and more preferably less than or equal to about 0.24. This will be described with reference to FIG. 6.

A plurality of acoustic wave devices were obtained in the same or substantially the same manner as the acoustic wave device in which the resonance characteristics illustrated in FIG. 5 were obtained except that d/2p was varied. FIG. 6 is an explanatory diagram illustrating the relationship between d/2p and the relative bandwidth of a resonator, where p is the center-to-center distance between adjacent electrodes or the average value of center-to-center distances and d is the average thickness of the piezoelectric layer 2 in the acoustic wave device of this preferred embodiment.

As illustrated in FIG. 6, for example, when d/2p exceeds about 0.25, i.e., d/p>about 0.5, the relative bandwidth is less than about 5%, even when d/p is adjusted. In contrast, when d/2p≤about 0.25, i.e., d/p≤about 0.5, if d/p is varied within this range, the relative bandwidth can be set to about 5% or more, i.e., a resonator with a high coupling coefficient can be configured. When d/2p is less than or equal to about 0.12, i.e., when d/p is less than or equal to about 0.24, the relative bandwidth can be increased to be greater than or equal to about 7%. In addition, if d/p is adjusted within this range, a resonator with an even wider relative bandwidth can be obtained and a resonator with an even higher coupling coefficient can be realized. Therefore, it is clear that a resonator using thickness-shear first-order-mode bulk waves and having a high coupling coefficient can be configured by setting d/p to about 0.5 or less, for example.

The at least one pair of electrodes may be one pair of electrodes, and p is the distance between the centers of the adjacent electrode fingers 3 and 4 when there is one pair of electrodes. In the case where there are 1.5 or more pairs of electrodes, p may be the average distance between the centers of adjacent electrode fingers 3 and 4.

If there are variations in the thickness d of the piezoelectric layer 2, an average value of the thickness may be used as the thickness d.

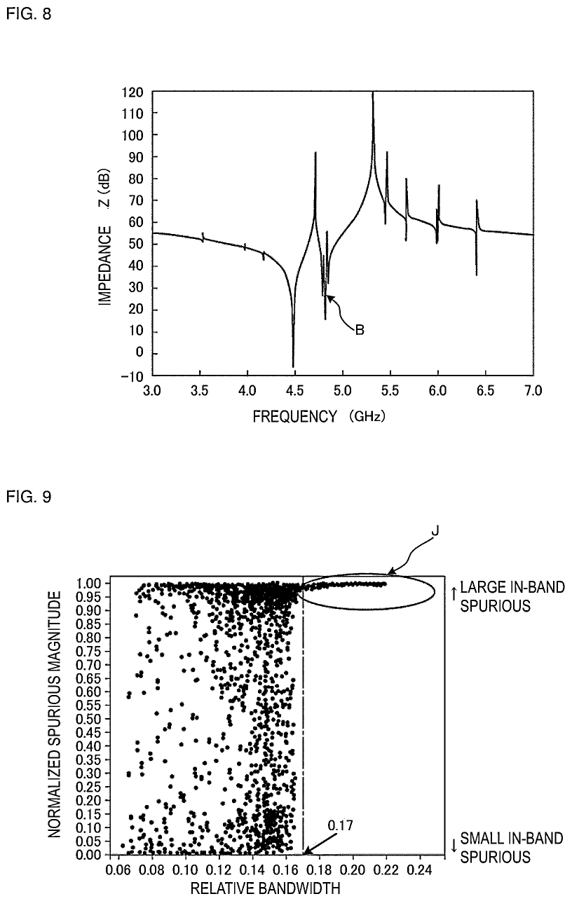

FIG. 7 is a plan view illustrating an example in which a pair of electrodes is provided in an acoustic wave device of this preferred embodiment. In an acoustic wave device 100, one pair of electrodes, including an electrode finger 3 and an electrode finger 4, is provided on a first main surface 2a of a piezoelectric layer 2.

K in FIG. 7 indicates the crossing width. As described above, an acoustic wave device according to a preferred embodiment may include one pair of electrodes. In this case, as long as d/p is, for example, about 0.5 or less, bulk waves of the thickness-shear first-order mode can be effectively excited.

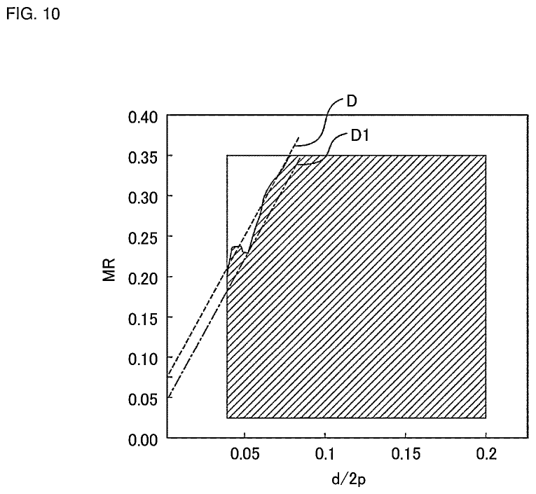

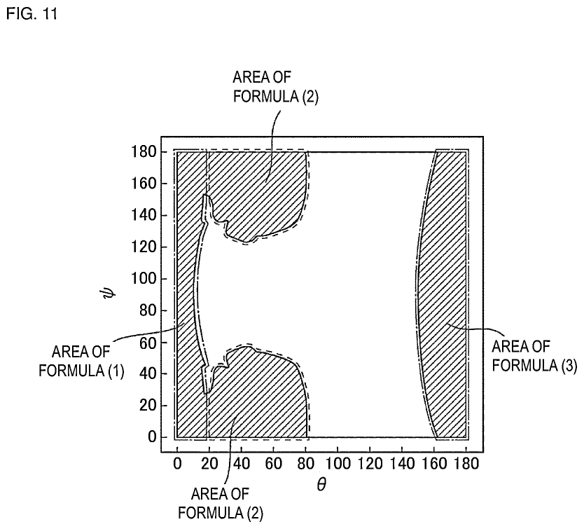

In the acoustic wave device 1, a metallization ratio MR of adjacent electrode fingers 3 and 4 with respect to the excitation region C, which is the region in which any adjacent electrode fingers 3 and 4 out of the plurality of electrode fingers 3 and 4 overlap in the direction in which the electrode fingers 3 and 4 face each other, preferably satisfies MR≤1.75(d/p)+0.075. In this case, spurious can be effectively reduced. This will be explained with reference to FIGS. 8 and 9.

FIG. 8 is a reference diagram illustrating an example of resonance characteristics of an acoustic wave device of this preferred embodiment. A spurious emission, as indicated by arrow B, appears between a resonant frequency and an anti-resonant frequency. For example, d/p=about 0.08 and Euler angles (0°, 0°, 90°) of LiNbO₃ were assumed. The metallization ratio MR=about 0.35 was used.

The metallization ratio MR will be described while referring to FIG. 1B. Focusing on one pair of electrode fingers 3 and 4, it is assumed that only one pair of electrode fingers 3 and 4 is provided in the electrode structure in FIG. 1B. In this case, the region surrounded by a single dot dashed line is the excitation region C. This excitation region C includes the region of the electrode finger 3 that overlaps the electrode finger 4, the region of electrode finger 4 that overlaps the electrode finger 3, and the region between the electrode finger 3 and the electrode finger 4 where the electrode finger 3 and the electrode finger 4 overlap, when the electrode finger 3 and the electrode finger 4 are viewed in a direction perpendicular or substantially perpendicular to the length direction of the electrode fingers 3 and 4, i.e., the direction in which the electrode fingers 3 and 4 face each other. The metallization ratio MR is the ratio of the area of electrode fingers 3 and 4 within the excitation region C to the area of the excitation region C. That is, the metallization ratio MR is the ratio of the area of the metallization portion to the area of the excitation region C.

When a plurality of pairs of electrode fingers 3 and 4 are provided, MR may be the ratio of the metallization parts included in the total excitation region C to the total area of the excitation region C.

FIG. 9 is an explanatory diagram illustrating the relationship between the relative bandwidth of an acoustic wave device of this preferred embodiment and the amount of phase rotation of the impedance of a spurious emission normalized using about 180 degrees as the magnitude of the spurious emission when a number of acoustic wave resonators are provided in the acoustic wave device of this preferred embodiment. The relative bandwidth was adjusted by changing the film thickness of the piezoelectric layer 2 and the dimensions of the electrode fingers 3 and 4 to various values. FIG. 9 illustrates results for a piezoelectric layer 2 made of Z-cut LiNbO₃, but a similar trend is observed for piezoelectric layers 2 with other cut angles.

In the region enclosed by an oval J in FIG. 9, the spurious emission is as large as about 1.0. It is clear from FIG. 9 that when the relative bandwidth exceeds about 0.17, i.e., about 17%, a large spurious emission having a spurious level of about 1 or higher appears inside the passband, even when the parameters used to obtain the relative bandwidth are varied. In other words, a large spurious emission, as indicated by arrow B, appears inside the band as in the resonance characteristics illustrated in FIG. 8. Therefore, the relative bandwidth is preferably, for example, about 17% or less. In this case, the spurious emission can be reduced by adjusting the film thickness of the piezoelectric layer 2, the dimensions of the electrode fingers 3 and 4, and so on.

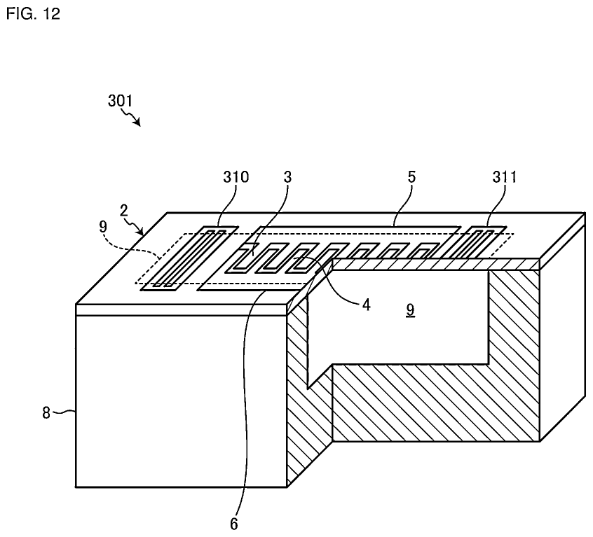

FIG. 10 is an explanatory diagram illustrating the relationship between d/2p, the metallization ratio MR, and the relative bandwidth. For the acoustic wave device 1 of this preferred embodiment, various acoustic wave devices 1 with different d/2p and MR were configured and the relative bandwidths were measured. The area shaded with hatching on the right side of a dashed line D in FIG. 10 is the region where the relative bandwidth is about 17% or less. The boundary between the region shaded with hatching and the region not shaded with hatching is expressed as MR=about 3.5(d/2p)+0.075. That is, MR=about 1.75(d/p)+0.075. Therefore, preferably, for example, MR≤about 1.75(d/p)+0.075. In this case, the relative bandwidth about 17% or less, for example, is easily achieved. The region to the right of MR=about 3.5(d/2p)+0.05 indicated by a single dot dashed line D1 in FIG. 10 is more preferable, for example. In other words, if MR≤about 1.75(d/p)+0.05, the relative bandwidth will reliably be about 17% or less, for example.

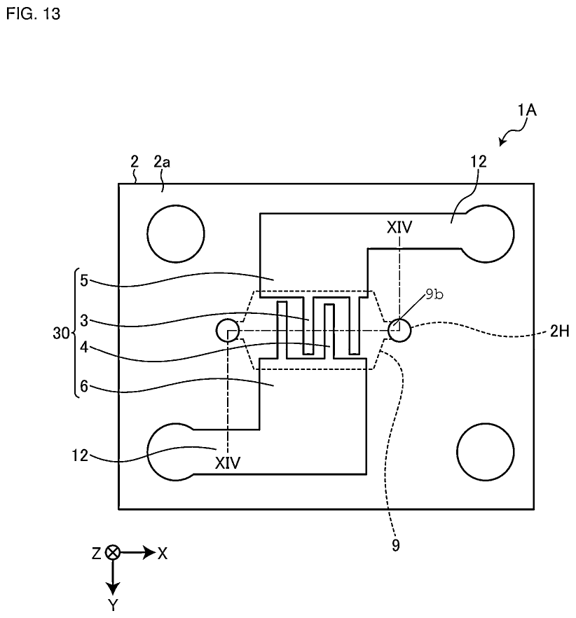

FIG. 11 is an explanatory diagram illustrating a relative bandwidth map for the Euler angles (0°, θ, ψ) of LiNbO₃ when d/p is as close to 0 as possible. The areas shaded with hatching in FIG. 11 are regions where, for example, a relative bandwidth of at least about 5% or more can be obtained. The ranges of these regions can be approximated by the following Formulas (1), (2), and (3).

(0°±10°, 0° to 20°, any ψ) Formula (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Formula (2)

(0°±10°, [180°−30° (1−(ψ−90)²/8100)^{1/2}] to 180°, any ψ) Formula (3)

Therefore, the Euler angle range of Formula (1), (2) or (3) is preferable because this allows the relative bandwidth to be sufficiently wide.

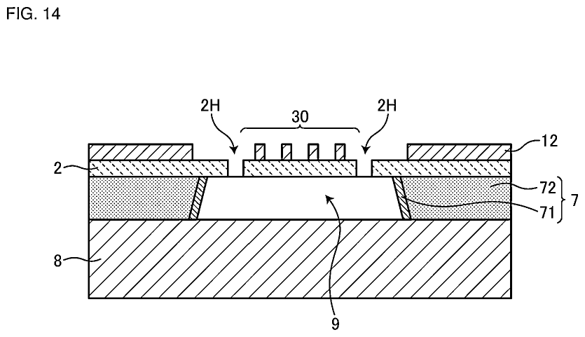

FIG. 12 is a partially cut-away perspective view for describing an acoustic wave device according to this preferred embodiment. In FIG. 12, the outer edge of the cavity 9 is indicated by a dashed line. An acoustic wave device according to a preferred embodiment of the present invention may utilize plate waves. In this case, as illustrated in FIG. 12, an acoustic wave device 301 includes reflectors 310 and 311. The reflectors 310 and 311 are provided at both sides of the electrode fingers 3 and 4 of the piezoelectric layer 2 in the acoustic wave propagation direction. In the acoustic wave device 301, Lamb waves are excited as plate waves by applying an AC electric field to the electrode fingers 3 and 4 above the cavity 9. Since the reflectors 310 and 311 are provided at both sides, resonance characteristics produced by Lamb waves as plate waves can be obtained.

As described above, in the acoustic wave devices 1 and 101, thickness-shear first-order-mode bulk waves are utilized. In addition, in the acoustic wave devices 1 and 101, the electrode fingers 3 and 4 are electrodes that are adjacent to each other, and when d represents the thickness of the piezoelectric layer 2 and p represents the distance between the centers of the adjacent electrode fingers 3 and 4, d/p is, for example, less than or equal to about 0.5. This enables the Q value to be increased even when the acoustic wave device is small in size.

In the acoustic wave devices 1 and 101, the piezoelectric layer 2 is made of, for example, lithium niobate or lithium tantalate. On the first main surface 2a or the second main surface 2b of the piezoelectric layer 2, there are the electrode fingers 3 and 4, which face each other in a direction that intersects the thickness direction of the piezoelectric layer 2, and the electrode fingers 3 and 4 are preferably covered with a protective film.

### First Preferred Embodiment

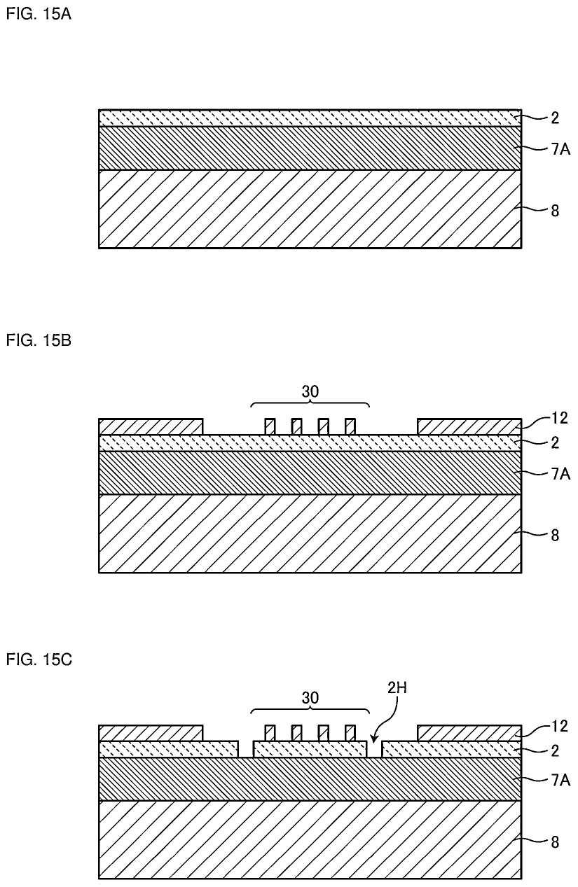

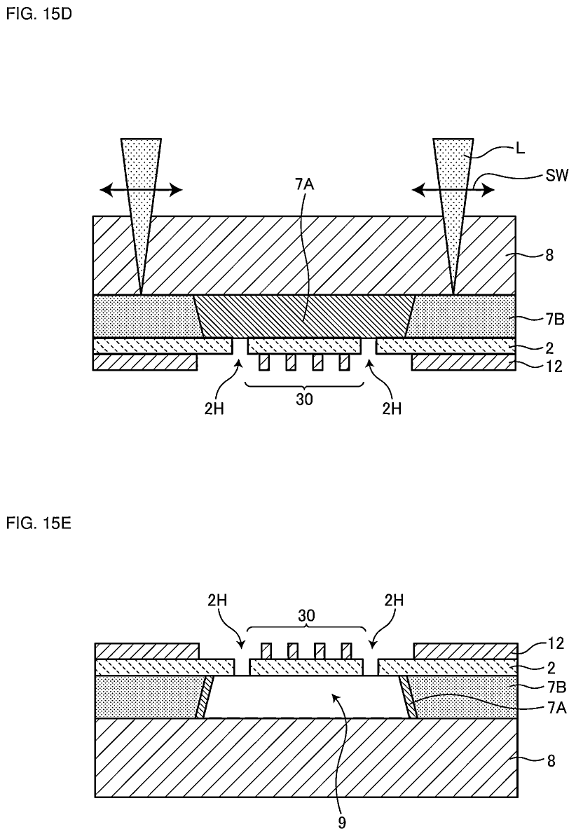

FIG. 13 is a plan view of an acoustic wave device according to a First Preferred Embodiment of the present invention. FIG. 14 is a sectional view taken along line XIV-XIV in FIG. 13. In the example illustrated in FIG. 13, a first busbar electrode 5 and a second busbar electrode 6 are connected to wiring lines 12 provided on a first main surface 2a of a piezoelectric layer 2, but this is merely an example.

As illustrated in FIGS. 13 and 14, in an acoustic wave device 1A according to the First Preferred Embodiment, a cavity 9 is provided on a surface of a support substrate 8 on the side where a piezoelectric layer 2 is located in the Z direction. The cavity 9 is provided so as to at least partially overlap a functional electrode 30 in plan view in the Z direction. As illustrated in FIG. 14, the cavity 9 is a space surrounded by the piezoelectric layer 2, the support substrate 8, and an intermediate layer 7. The cavity 9 may be a space surrounded by the piezoelectric layer 2 and the intermediate layer 7. The support substrate 8 is a translucent substrate, for example, quartz. The intermediate layer 7 is, for example, a layer made of an organic material. The piezoelectric layer includes, for example, lithium niobate or lithium tantalate. The piezoelectric layer 2 may include lithium niobate or lithium tantalate and unavoidable impurities. The functional electrode 30 is an IDT electrode. Here, the IDT electrode includes a first busbar electrode 5 and a second busbar electrode 6, which face each other, electrode fingers 3 connected to the first busbar electrode 5, and electrode fingers 4 connected to the second busbar electrode 6. In the First Preferred Embodiment, the functional electrode 30 is provided on the first main surface 2a of the piezoelectric layer 2, but may instead be provided on the second main surface of the piezoelectric layer 2, which is on the opposite side from the first main surface 2a.

As illustrated in FIG. 13, in the acoustic wave device 1A according to the First Preferred Embodiment, openings 2H (through holes) that extend through the piezoelectric layer 2 are provided in the piezoelectric layer 2 at positions overlapping recesses 9b of the cavity 9 in plan view in the Z direction.

In the intermediate layer 7, the amount of crystallized component in a first portion 71, which is near the cavity 9, is different from the amount of crystallized component in a second portion 72, which is far from the cavity 9. In other words, the second portion 72 is modified compared to the first portion 71. According to this configuration, the second portion 72 of the intermediate layer 7 is modified compared to the first portion 71, and as a result, the second portion 72 is more difficult to etch than the first portion 71.

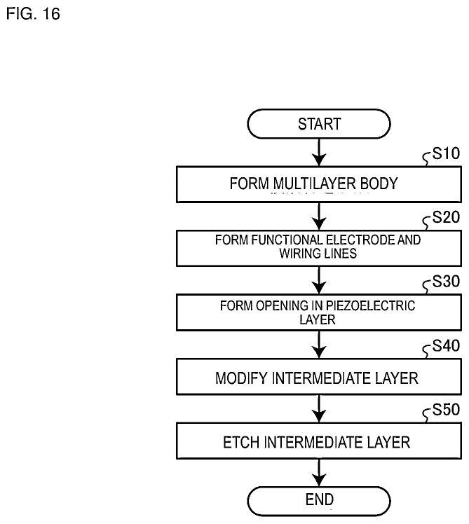

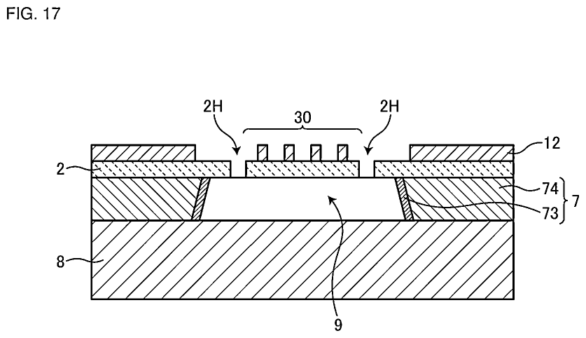

FIG. 15A is a diagram illustrating a bonding step of an acoustic wave device manufacturing method according to a preferred embodiment of the present invention. FIG. 15B is a diagram illustrating an electrode forming step of an acoustic wave device manufacturing method according to a preferred embodiment of the present invention. FIG. 15C is a diagram illustrating an opening forming step of an acoustic wave device manufacturing method according to a preferred embodiment of the present invention. FIG. 15D is a diagram illustrating a modifying step of an acoustic wave device manufacturing method according to a preferred embodiment of the present invention. FIG. 15E is a diagram illustrating an etching step of an acoustic wave device manufacturing method according to a preferred embodiment of the present invention. FIG. 16 is a flowchart illustrating an example of an acoustic wave device manufacturing method of the First Preferred Embodiment. Hereafter, an acoustic wave device manufacturing method of the First Preferred Embodiment will be described while referring to FIGS. 15A to 15E and FIG. 16.

As illustrated in FIGS. 15A and 16, the intermediate layer 7 is formed on the support substrate 8. An intermediate layer 7A is made of, for example, a photo-curable polyimide resin, which is an organic material including crystalline polyimide resin. Crystalline polyimide resin is, for example, BPDA-based polyimide (3,4,3′,4′-biphenyltetracarboxylicdianhydride). The piezoelectric layer 2 is stacked so as to overlap the intermediate layer 7A, and a multilayer body is formed (Step S10).

Next, as illustrated in FIGS. 15B and 16, the functional electrode 30 and the wiring lines 12 connected to the functional electrode 30 are formed using, for example, a lift-off method or the like (Step S20).

Next, portions of the piezoelectric layer 2 are covered with a resist, and the portions of the piezoelectric layer 2 on which the resist is not formed is etched to form the openings 2H (through holes) that penetrate through the piezoelectric layer 2, as illustrated in FIGS. 15C and 16 (Step S30). Then, the formed resist is removed.

Next, as illustrated in FIG. 15D and FIG. 16, a laser L is radiated through the support substrate 8 from the rear surface side of the support substrate 8 (the main surface on the opposite side from the intermediate layer 7A). A region outside the openings 2H (region that does not overlap the functional electrode 30 in plan view in the stacking direction of the support substrate 8 and the piezoelectric layer 2) is irradiated with the laser L. The intermediate layer 7A is modified into an intermediate layer 7B in a region SW irradiated with the laser L (Step S40). Specifically, the layer is modified such that polymerization of the organic material irradiated with the laser L is promoted and etching using a solvent is inhibited. Instead of laser irradiation, ion irradiation or electron beam irradiation may be applied to the region SW. The intermediate layer 7A and the intermediate layer 7B are subjected to different degrees of laser, ion, or electron beam irradiation.

As illustrated in FIGS. 15E and 16, a resist for surface protection is patterned on the piezoelectric layer 2, the functional electrode 30, and the wiring lines 12, and the intermediate layer 7A is etched using an organic solvent injected through the openings 2H (Step S50). As a result, the intermediate layer 7A in a region other than the modified region SW (the region inward from the openings 2H (through holes)) is removed, and the cavity 9, which overlaps the functional electrode 30 in plan view, is formed. Thus, the intermediate layer 7B becomes the second portion 72 and the intermediate layer 7A remaining in the portion along the cavity 9 in the intermediate layer 7B becomes the first portion. Finally, manufacture of the acoustic wave device of the First Preferred Embodiment can be completed by peeling off the patterned resist.

Thus, the acoustic wave device manufacturing method includes a bonding step (Step S10), a modifying step (Step S40), and a cavity forming step (Step S50). In the bonding step (Step S10), the support substrate 8 and the piezoelectric layer 2 are bonded to each other via the intermediate layer 7A. In the modifying step (Step S40), after the bonding step, the intermediate layer 7A, which is modified and surrounded by the second portion 72 of the intermediate layer 7B, becomes the first portion 71, and thus the first portion 71, which is more soluble in a prescribed solvent than the second portion 72, is formed. In the cavity forming step (Step S50), a portion of the intermediate layer 7A is dissolved to form the cavity 9. Solvents, which are called etchants, are organic solvents, for example, cyclopentanone, Pgmea, and so on.

As described above, the acoustic wave device 1A according to the First Preferred Embodiment includes the support substrate 8 having a thickness in the first direction, the piezoelectric layer 2 adjacent to the support substrate 8 in the first direction, and the functional electrode 30 provided on the piezoelectric layer 2 in the first direction. The functional electrode 30 includes a plurality of electrode fingers 3 extending in the second direction perpendicular or substantially perpendicular to the first direction, and a plurality of electrode fingers 4 each facing one of the plurality of electrode fingers 3 in the third direction perpendicular or substantially perpendicular to the first direction and the second direction and extending in the second direction. The cavity 9 is provided in the intermediate layer 7. The intermediate layer 7 includes the first portion 71 and the second portion 72, the first portion 71 is closer to the cavity 9 than the second portion 72, and the first portion 71 is more soluble in a prescribed solvent than the modified second portion 72.

Therefore, since the cavity 9 can be formed without having to provide a sacrificial layer made of a different material from the second portion 72, the boundary between the first and second portions 71 and 72 is less likely to be uneven, and variations in the film thickness of the piezoelectric layer 2 are more easily reduced or prevented.

Preferably, the first portion 71 of the intermediate layer 7 and the second portion 72 of the intermediate layer 7 are made of, for example, organic polyimides having the same crystallinity but different degrees of polymerization. Polymerization of the second portion 72 proceeds to a greater degree than that of the first portion 71, making the second portion 72 less likely to dissolve in an organic solvent, and this results in a higher proportion of crystalline polyimide content. The second portion 72 has a higher heat resistance because of the higher crystalline polyimide content. As described above, the heat resistance and the degree of solubility in an organic solvent can be adjusted in accordance with the modified degree of polymerization by using an organic material for the intermediate layer 7A.

The intermediate layer 7 may be made of silicon, for example. Specifically, for example, the intermediate layer 7A is silicon that has been formed in advance so as to include an amorphous layer using, for example, ion irradiation or another method. In this case as well, the intermediate layer 7B is formed by modifying and crystallizing the amorphous silicon by carrying out laser irradiation from the rear surface side of the support substrate 8.

The resulting first portion 71 is crystalline and the second portion 72 is amorphous. The crystallized component of the first portion 71 is different from the crystallized component of the second portion 72. Since amorphous silicon and crystallized silicon are the same type of material, unevenness is less likely to occur at the boundary between the amorphous silicon and the crystallized silicon. As a result, variations in film thickness between the portions of the piezoelectric layer 2 in contact with the amorphous silicon and crystallized silicon can be reduced or prevented.

Preferably, the support substrate 8 is translucent. This allows the laser L transmitted through the support substrate 8 to be used to modify the intermediate layer 7A so that the intermediate layer 7A becomes the intermediate layer 7B.

Preferably, when p is the distance between the centers of adjacent electrode fingers 3 and 4 of the plurality of electrode fingers 3 and 4, the thickness of the piezoelectric layer 2 is 2p or less. This enables the acoustic wave device 1 to be reduced in size and the Q value to be increased.

More preferably, the piezoelectric layer 2 includes, for example, lithium niobate or lithium tantalate. This enables an acoustic wave device having good resonance characteristics to be provided.

More preferably, the Euler angles (φ, θ, ψ) of the lithium niobate or lithium tantalate of the piezoelectric layer 2 preferably lie in the range defined by Formula (1), (2), or (3) given below. In this case, the relative bandwidth can be made sufficiently wide.

(0°±10°, 0° to 20°, any ψ) Formula (1)

(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Formula (2)

(0°±10°, [180°−30° (1−(ψ−90)²/8100)^{1/2}] to 180°, any ψ) Formula (3)

Preferably, the acoustic wave device 1 is configured to be able to utilize thickness-shear mode bulk waves. This enables an acoustic wave device having an increased coupling coefficient and good resonance characteristics to be provided.

Preferably, d/p about 0.5, for example, where d is the thickness of the piezoelectric layer 2 and p is the distance between the centers of adjacent electrode fingers 3 and 4. This enables the acoustic wave device 1 to be reduced in size and the Q value to be increased.

More preferably, d/p is about 0.24 or less, for example. This enables the acoustic wave device 1 to be reduced in size and the Q value to be increased.

Preferably, when the excitation region C is the region where adjacent electrode fingers 3 and 4 overlap in the direction in which the electrode fingers 3 and 4 face each other and MR is the metallization ratio of the plurality of electrode fingers 3 and 4 to the excitation area C, MR≤about 1.75(d/p)+0.075 is satisfied, for example. In this case, the relative bandwidth can be reliably made about 17% or less, for example.

Preferably, the acoustic wave device 301 is configured to be able to utilize plate waves. This enables an acoustic wave device having good resonance characteristics to be provided.

### Second Preferred Embodiment

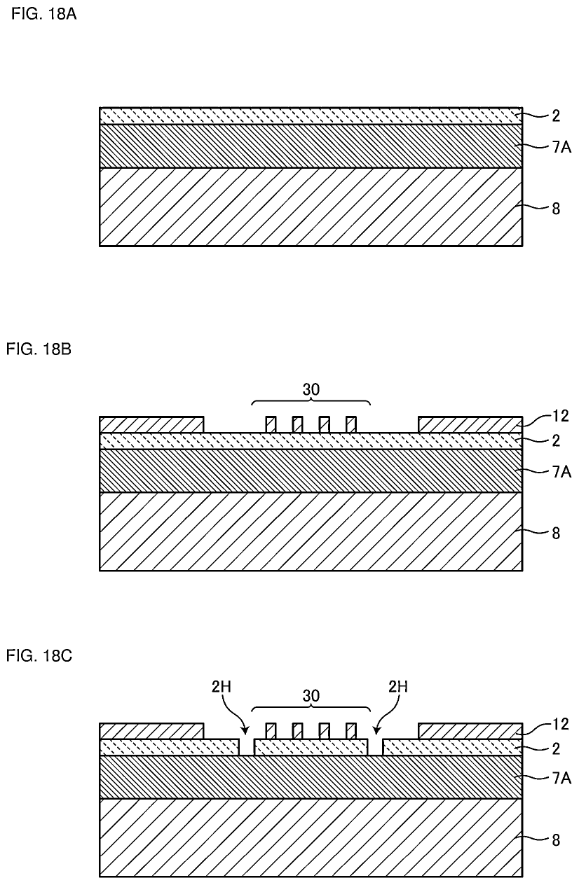

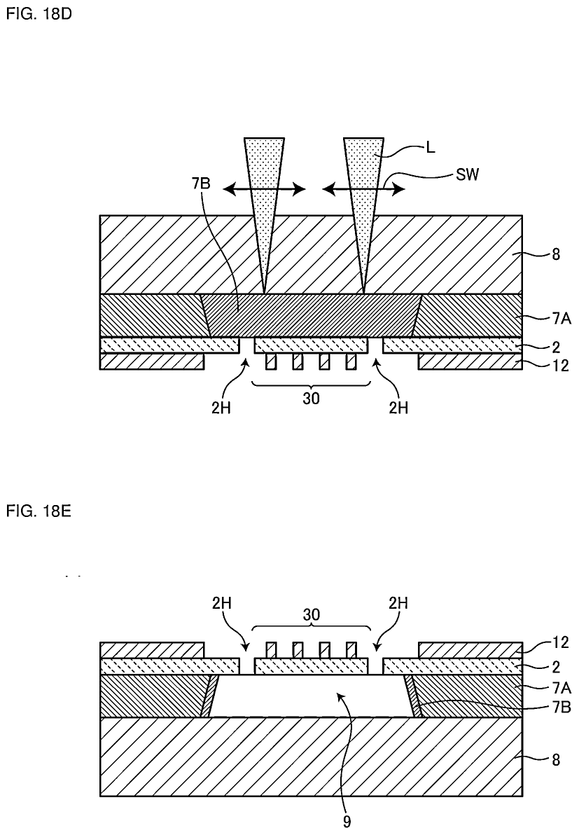

FIG. 17 is a diagram illustrating another example of a cross section taken along line XIV-XIV in FIG. 13 in a Second Preferred Embodiment of the present invention. FIG. 18A is a diagram illustrating a bonding step of an acoustic wave device manufacturing method according to a preferred embodiment of the present invention. FIG. 18B is a diagram illustrating an electrode forming step of an acoustic wave device manufacturing method according to a preferred embodiment of the present invention. FIG. 18C is a diagram illustrating an opening forming step of an acoustic wave device manufacturing method according to a preferred embodiment of the present invention. FIG. 18D is a diagram illustrating a modifying step of an acoustic wave device manufacturing method according to a preferred embodiment of the present invention. FIG. 18E is a diagram illustrating an etching step of an acoustic wave device manufacturing method according to a preferred embodiment of the present invention. Hereafter, a Second Preferred Embodiment and a manufacturing method therefor will be described while referring to FIG. 13, FIG. 16, and FIGS. 18A to 18E.

In an intermediate layer 7, the amount of crystallized component in a first portion 73, which is near a cavity 9, is different from the amount of crystallized component in a second portion 74, which is far from the cavity 9. In other words, the first portion 73 is modified compared to the second portion 74. With this configuration, the first portion 73 of the intermediate layer 7 is modified compared to the second portion 74, and as a result, the first portion 73 is more easily etched with a solvent than the second portion 74.

As illustrated in FIGS. 18A and 16, the intermediate layer 7 is formed on the support substrate 8. An intermediate layer 7A is made of, for example, a photo-curable polyimide resin, which is an organic material including crystalline polyimide resin. The piezoelectric layer 2 is stacked so as to overlap the intermediate layer 7A, and a multilayer body is formed (Step S10). The support substrate 8 is a translucent substrate, for example, quartz.

Next, as illustrated in FIGS. 18B and 16, the functional electrode 30 and the wiring lines 12 connected to the functional electrode 30 are formed using, for example, a lift-off method or the like (Step S20).

Next, a portion of the piezoelectric layer 2 is covered with a resist, and the portion of the piezoelectric layer 2 on which the resist is not formed is etched to form the openings 2H (through holes) through the piezoelectric layer 2, as illustrated in FIGS. 18C and 16 (Step S30). Then, the formed resist is removed.

Next, as illustrated in FIG. 18D and FIG. 16, a laser L is radiated through the support substrate 8 from the rear surface side of the support substrate 8 (the main surface on the opposite side from the intermediate layer 7A). A region inward from the openings 2H (a region that overlaps the functional electrode 30 in plan view in the stacking direction of the support substrate 8 and the piezoelectric layer 2) is irradiated with the laser L. The intermediate layer 7A is modified into an intermediate layer 7B in a region SW irradiated with the laser L (Step S40). Specifically, the layer is modified such that carbonization of the organic material irradiated with the laser L is promoted and etching using a solvent is promoted. Instead of laser irradiation, for example, ion irradiation or electron beam irradiation may be applied to the region SW. The intermediate layer 7A and the intermediate layer 7B are subjected to different degrees of laser, ion, or electron beam irradiation.

As illustrated in FIGS. 18E and 16, a resist for surface protection is patterned on the piezoelectric layer 2, the functional electrode 30, and the wiring lines 12, and the intermediate layer 7B is etched using an organic solvent injected through the openings 2H (Step S50). As a result, the intermediate layer 7B in a region other than the modified region SW (a region inward from the openings 2H (through holes)) is removed, and the cavity 9, which overlaps the functional electrode 30 in plan view, is formed. Thus, the intermediate layer 7A becomes the second portion 74 and the intermediate layer 7B remaining in the portion along the cavity 9 in the intermediate layer 7A becomes the first portion. Finally, manufacture of the acoustic wave device of the Second Preferred Embodiment can be completed by peeling off the patterned resist.

Thus, the acoustic wave device manufacturing method includes a bonding step (Step S10), a modifying step (Step S40), and a cavity forming step (Step S50). In the bonding step (Step S10), the support substrate 8 and the piezoelectric layer 2 are bonded to each other via the intermediate layer 7A. In the modifying step (Step S40), after the bonding step, the intermediate layer 7A surrounded by the second portion 72 of the intermediate layer 7B is modified and becomes the first portion 71, and thus the first portion 71, which is more soluble in a prescribed solvent than the second portion 72, is formed. In the cavity forming step (Step S50), part of the intermediate layer 7A is dissolved to form the cavity 9.

As described above, the acoustic wave device 1A according to the Second Preferred Embodiment includes the support substrate 8 having a thickness in the first direction, the piezoelectric layer 2 adjacent to the support substrate 8 in the first direction, and the functional electrode 30 provided on the piezoelectric layer 2 in the first direction. The functional electrode 30 includes a plurality of electrode fingers 3 extending in the second direction perpendicular or substantially perpendicular to the first direction, and a plurality of electrode fingers 4 each facing one of the plurality of electrode fingers 3 in the third direction perpendicular or substantially perpendicular to the first direction and the second direction and extending in the second direction. The cavity 9 is provided in the intermediate layer 7. The intermediate layer 7 includes the first portion 73 and the second portion 74, the first portion 73 is closer to the cavity 9 than the second portion 74, and the modified first portion 73 is more soluble in a prescribed solvent than the second portion 74.

Therefore, since the cavity 9 can be formed without having to provide a sacrificial layer composed of a different material from the second portion 74, the boundary between the first and second portions 73 and 74 is unlikely to be uneven, and variations in the film thickness of the piezoelectric layer 2 are more easily reduced or prevented.

Preferably, the first portion 73 of the intermediate layer 7 and the second portion 74 of the intermediate layer 7 are made of the same organic material, but have different degrees of carbonization as crystallinity. By using an organic material for the intermediate layer 7A, the solubility in an organic solvent can be adjusted in accordance with the degree of modified carbonization.

Preferably, the support substrate 8 is translucent. This enables the laser L transmitted through the support substrate 8 to be used to modify the intermediate layer 7A.

### Third Preferred Embodiment

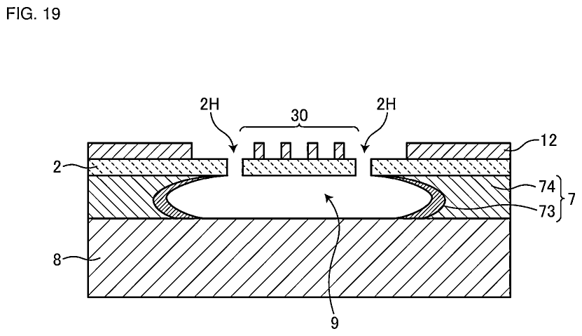

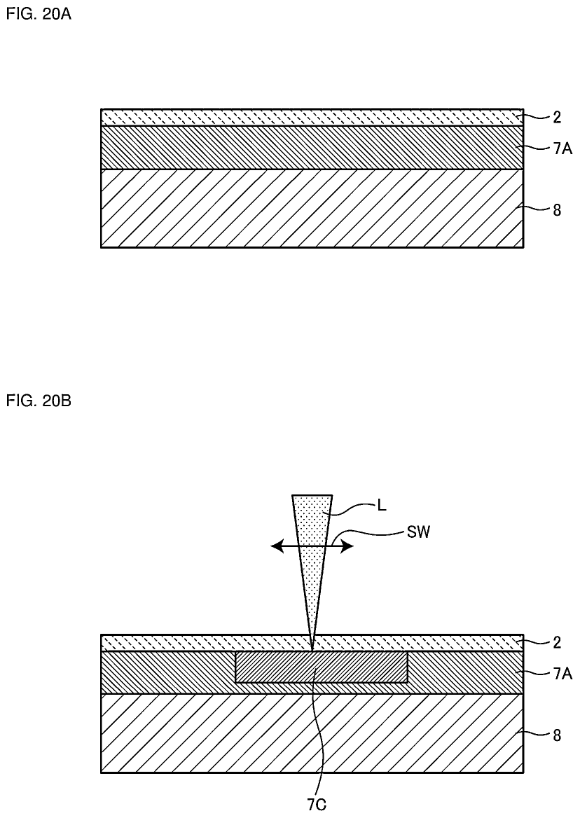

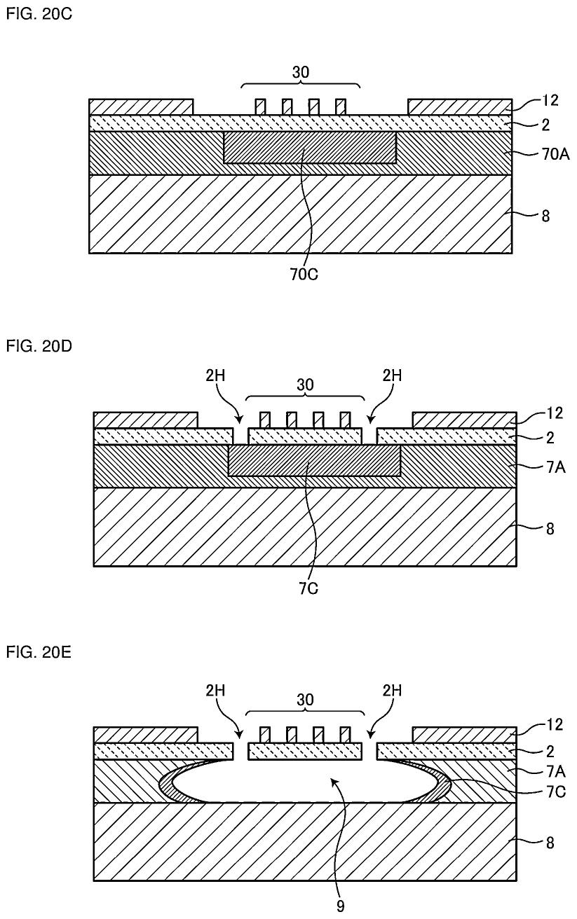

FIG. 19 is a diagram illustrating another example of a cross section taken along line XIV-XIV in FIG. 13 in a Third Preferred Embodiment of the present invention. FIG. 20A is a diagram illustrating a bonding step of an acoustic wave device manufacturing method according to a preferred embodiment of the present invention. FIG. 20B is a diagram illustrating a modifying step of an acoustic wave device manufacturing method according to a preferred embodiment of the present invention. FIG. 20C is a diagram illustrating an electrode forming step of an acoustic wave device manufacturing method according to a preferred embodiment of the present invention. FIG. 20D is a diagram illustrating an opening forming step of an acoustic wave device manufacturing method according to a preferred embodiment of the present invention. FIG. 20E is a diagram illustrating an etching step of an acoustic wave device manufacturing method according to a preferred embodiment of the present invention. FIG. 21 is a flowchart illustrating an example of an acoustic wave device manufacturing method according to a preferred embodiment of the present invention. Hereafter, a Third Preferred Embodiment and a manufacturing method according to a preferred embodiment of the present invention therefor will be described while referring to FIG. 13, FIG. 19, FIGS. 20A to 20E, and FIG. 21.

In an intermediate layer 7, the amount of crystallized component in a first portion 73, which is near a cavity 9, is different from the amount of crystallized component in a second portion 74, which is far from the cavity 9. In other words, the first portion 73 is modified compared to the second portion 74. With this configuration, the first portion 73 of the intermediate layer 7 is modified compared to the second portion 74, and as a result, the first portion 73 is more easily etched with a solvent than the second portion 74.

As illustrated in FIGS. 20A and 21, the intermediate layer 7 is formed on the support substrate 8. An intermediate layer 7A is made of, for example, a photo-curable polyimide resin, which is an organic material containing crystalline polyimide resin. The piezoelectric layer 2 is stacked so as to overlap the intermediate layer 7A, and a multilayer body is formed (Step S10).

Next, as illustrated in FIGS. 20B and 21, the laser L is radiated from the front surface side of the piezoelectric layer 2 (main surface on the intermediate layer 7A side). A region inward from the openings 2H (region that overlaps a prescribed region where the functional electrode 30 is to be formed in plan view in the stacking direction of the support substrate 8 and the piezoelectric layer 2) is irradiated with the laser L. The intermediate layer 7A is modified into an intermediate layer 7B in a region SW irradiated with the laser L (Step S21). Specifically, peeling off occurs at the bonding interface between the piezoelectric layer 2 and the organic material irradiated with the laser L. The organic material irradiated with the laser L may be polymerized to a greater degree than the intermediate layer 7A or carbonized to a greater degree than the intermediate layer 7A. Instead of laser irradiation, ion irradiation or electron beam irradiation may be applied to the region SW.

Next, as illustrated in FIGS. 20C and 21, the functional electrode 30 and the wiring lines 12 connected to the functional electrode 30 are formed using, for example, a lift-off method or the like (Step S31).

Next, a portion of the piezoelectric layer 2 is covered with a resist, and the portion of the piezoelectric layer 2 on which the resist is not formed is etched to form openings 2H (through holes) through the piezoelectric layer 2, as illustrated in FIGS. 20D and 21 (Step S41). Then, the formed resist is removed.

As illustrated in FIGS. 20E and 21, a resist for surface protection is patterned on the piezoelectric layer 2, the functional electrode 30, and the wiring lines 12, and the intermediate layer 7B is etched using an organic solvent injected through the openings 2H (Step S51). Etching of intermediate layer 7B proceeds isotropically and side etching of intermediate layer 7A also occurs, but the etching proceeds from the peeling off interface between the intermediate layer 7B and the piezoelectric layer 2, and the reaction finishes before the side etching becomes significant. As a result, the intermediate layer 7B in a region other than the modified region SW (the region inward from the openings 2H (through holes)) is removed, and the cavity 9, which overlaps the functional electrode 30 in plan view, is formed. Thus, the intermediate layer 7A becomes the second portion 74, and the portion of the intermediate layer 7A remaining along the cavity 9 and in contact with the solvent becomes the first portion. Finally, manufacture of the acoustic wave device of the Third Preferred Embodiment can be completed by peeling off the patterned resist.

As described above, the acoustic wave device 1A according to the Third Preferred Embodiment includes the support substrate 8 having a thickness in the first direction, the piezoelectric layer 2 adjacent to the support substrate 8 in the first direction, and the functional electrode 30 provided on the piezoelectric layer 2 in the first direction. The functional electrode 30 includes a plurality of electrode fingers 3 extending in the second direction perpendicular to the first direction, and a plurality of electrode fingers 4 each facing one of the plurality of electrode fingers 3 in the third direction perpendicular to the first direction and the second direction and extending in the second direction. The cavity 9 is provided in the intermediate layer 7. The intermediate layer 7 includes the first portion 73 and the second portion 74, the first portion 73 is closer to the cavity 9 than the second portion 74, and the modified first portion 73 is more soluble in a prescribed solvent than the second portion 74.

Therefore, since the cavity 9 can be formed without having to provide a sacrificial layer composed of a different material from the second portion 74, the boundary between the first and second portions 73 and 74 is unlikely to be uneven, and variations in the film thickness of the piezoelectric layer 2 are more easily reduced or prevented.

In the Third Preferred Embodiment, the laser L does not have to pass through the support substrate 8, and therefore the support substrate 8 does not have to be a translucent substrate. The support substrate 8 may be made of, for example, silicon, aluminum oxide, quartz, and so on.

### Modification of Third Preferred Embodiment

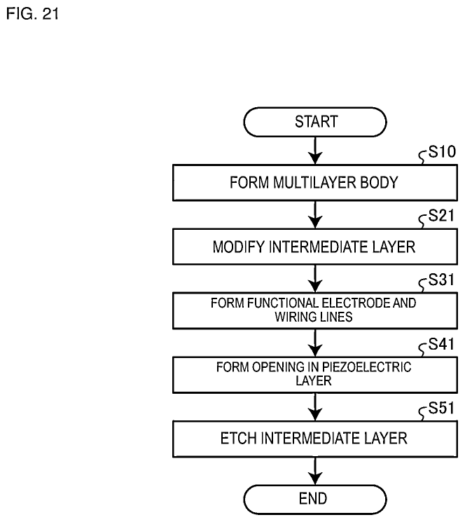

FIG. 22 is a diagram illustrating an example of a cross section taken along line XIV-XIV in FIG. 13 in a modification of the Third Preferred Embodiment. In the modification of the Third Preferred Embodiment, the intermediate layer 7 is a multilayer body including a metal layer 75 and an organic material (first portion 73 and second portion 74).

The metal layer 75 having metallic luster and the piezoelectric layer 2 sandwich the organic material (first portion 73 and second portion 74) therebetween. Therefore, when the laser L is radiated from the front surface side (main surface on intermediate layer 7A side) of the piezoelectric layer 2 (Step S21), the intermediate layer 7A is easily modified to form the intermediate layer 7B by the reflected light of the laser L reflected by the metal layer 75.

The intermediate layer 7 may be a multilayer body consisting of the metal layer 75 and an inorganic material.

### Fourth Preferred Embodiment

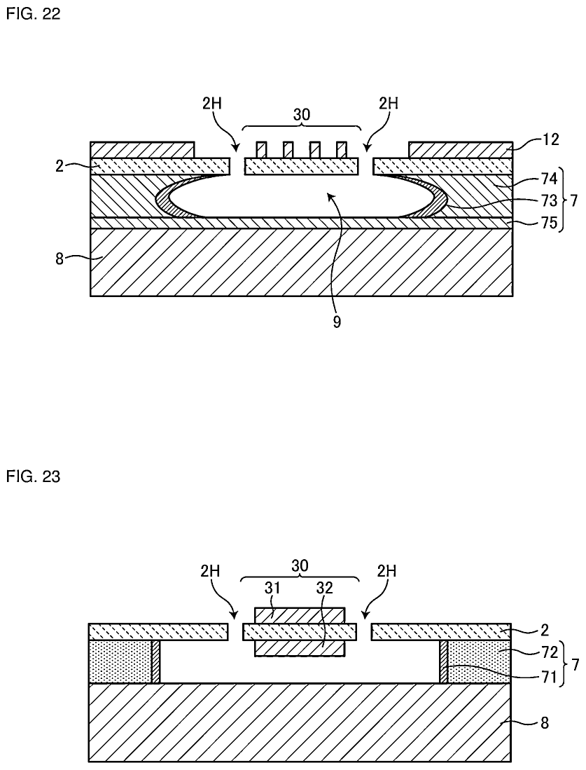

FIG. 23 is a diagram illustrating another example of a cross section of a functional electrode in a Fourth Preferred Embodiment of the present invention. The functional electrode 30 of the Fourth Preferred Embodiment includes an upper electrode 31 and a lower electrode 32. The piezoelectric layer 2 is sandwiched between the upper electrode 31 and the lower electrode 32 in the thickness direction. The acoustic wave device of the Fourth Preferred Embodiment may also be referred to as a bulk acoustic wave device (BAW device).

In the intermediate layer 7, the amount of crystallized component in a first portion 71, which is near the cavity 9, is different from the amount of crystallized component in a second portion 72, which is far from the cavity 9. In other words, the second portion 72 is modified compared to the first portion 71. According to this configuration, the second portion 72 of the intermediate layer 7 is modified compared to the first portion 71, and as a result, the second portion 72 is more difficult to etch than the first portion 71.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate with a thickness in a first direction;
an intermediate layer on the support substrate;
a piezoelectric layer adjacent to the support substrate in the first direction; and
a functional electrode on the piezoelectric layer; wherein a cavity is provided in the intermediate layer; and
the intermediate layer includes a first portion and a second portion, the first portion is closer to the cavity than the second portion, and the first portion is more soluble in a prescribed etchant than the second portion.

2. An acoustic wave device comprising:
a support substrate with a thickness in a first direction;
an intermediate layer on the support substrate;
a piezoelectric layer adjacent to the support substrate in the first direction; and
a functional electrode on the piezoelectric layer; wherein a cavity is provided in the intermediate layer; and
the intermediate layer includes a first portion and a second portion, the first portion is closer to the cavity than the second portion, and the first portion is less soluble in a prescribed etchant than the second portion.

3. The acoustic wave device according to claim 1, wherein an amount of crystallized component of the first portion is different from an amount of crystallized component of the second portion.

4. The acoustic wave device according to claim 1, wherein an amount of crystallized component of the first portion is smaller than an amount of crystallized component of the second portion.

5. The acoustic wave device according to claim 1, wherein the first portion and the second portion have different degrees of carbonization from each other.

6. The acoustic wave device according to claim 2, wherein the first portion has a greater degree of carbonization than the second portion.

7. The acoustic wave device according to claim 1, wherein the intermediate layer includes an inorganic material.

8. The acoustic wave device according to claim 2, wherein the intermediate layer includes an organic material including a crystalline polyimide resin that is photo-curable.

9. The acoustic wave device according to claim 2, wherein the intermediate layer is a multilayer body including a metal layer and an organic material including a crystalline polyimide resin that is photo-curable.

10. The acoustic wave device according to claim 1, wherein the support substrate is translucent.

11. The acoustic wave device according to claim 1, wherein
the functional electrode includes one or more first electrode fingers extending in a second direction that intersects the first direction, and one or more second electrode fingers extending in the second direction and facing any of the one or more first electrode fingers in a third direction perpendicular or substantially perpendicular to the second direction; and
when p is a distance between centers of adjacent first and second electrode fingers of the one or more first electrode fingers and the one or more second electrode fingers, a thickness of the piezoelectric layer is about 2p or less.

12. The acoustic wave device according to claim 11, wherein the piezoelectric layer includes lithium niobate or lithium tantalate.

13. The acoustic wave device according to claim 12, wherein the acoustic wave device is structured to generate thickness-shear mode bulk waves.

14. The acoustic wave device according to claim 1, wherein
the functional electrode includes one or more first electrode fingers extending in a second direction that intersects the first direction, and one or more second electrode fingers extending in the second direction and each facing any of the one or more first electrode fingers in a third direction perpendicular or substantially perpendicular to the second direction; and
when d is a thickness of the piezoelectric layer and p is a distance between centers of adjacent first and second electrode fingers of the one or more first electrode fingers and the one or more second electrode fingers, d/p is about 0.5 or less.

15. The acoustic wave device according to claim 14, wherein d/p is about 0.24 or less.

16. The acoustic wave device according to claim 1, wherein the functional electrode includes one or more first electrode fingers extending in a second direction that intersects the first direction and a plurality of second electrode fingers extending in the second direction and each facing any of the one or more first electrode fingers in a third direction perpendicular or substantially perpendicular to the second direction; and
when a region where adjacent ones of the first and second electrode fingers overlap when viewed in the direction in which the first and second electrode fingers face each other is an excitation region and a metallization ratio of the one or more first electrode fingers and the plurality of second electrode fingers to the excitation region is MR, MR≤about 1.75(d/p)+0.075 is satisfied.

17. The acoustic wave device according to claim 1, wherein the acoustic wave device is structured to generate plate waves.

18. The acoustic wave device according to claim 1, wherein Euler angles (φ, θ, ψ) of lithium niobate or lithium tantalate of the piezoelectric layer are within a range of Formula (1), (2), or (3):
(0°±10°, 0° to 20°, any ψ) Formula (1);
(0°±10°, 20° to 80°, 0° to 60° (1−(θ−50)²/900)^{1/2}) or (0°±10°, 20° to 80°, [180°−60° (1−(θ−50)²/900)^{1/2}] to 180°) Formula (2); and
(0°±10°, [180°−30° (1−(ψ−90)²/8100)^{1/2}] to 180°, any ψ) Formula (3).

19. An acoustic wave device manufacturing method comprising:
bonding a support substrate and a piezoelectric layer to each other via an intermediate layer;
after the bonding, forming and modifying a first portion of the intermediate layer surrounded by a second portion of the intermediate layer and being more soluble in a prescribed etchant than the second portion; and
forming a cavity by dissolving the first portion of the intermediate layer formed in the forming and modifying.

20. The acoustic wave device manufacturing method according to claim 19, wherein in the forming and modifying, one of laser irradiation, ion irradiation, and electron beam irradiation is applied, and different degrees of the laser irradiation, ion irradiation, or electron beam irradiation are applied to the first and second portions.

21. The acoustic wave device manufacturing method according to claim 19, wherein
the support substrate is translucent; and
in the forming and modifying, laser light passes through the support substrate.
